(19) United States
(12) Patent Application Publication
(10) Pub. No.: US 2022/0329261 A1
(43) Pub. Date: Oct. 13, 2022

(54) DECODING METHOD, DECODING DEVICE, CONTROL CIRCUIT, AND PROGRAM STORAGE MEDIUM

(71) Applicant: Mitsubishi Electric Corporation, Tokyo (JP)

(72) Inventor: Takahiko NAKAMURA, Tokyo (JP)

(73) Assignee: Mitsubishi Electric Corporation, Tokyo (JP)

(21) Appl. No.: 17/848,249

(22) Filed: Jun. 23, 2022

Related U.S. Application Data
(63) Continuation of application No. PCT/JP2020/008111, filed on Feb. 27, 2020.

(51) Int. Cl. H03M 13/11

(52) U.S. Cl. CPC H03M 13/1145; H03M 13/1168; H03M 13/1134

(57) ABSTRACT

A decoding method includes a selection step of reading reception data from a storage unit in units of P words, of reproducing data based on a column weight of a P-column unit of a check matrix, of writing reproduced data into an intermediate value storage unit, and of reading data from as many applicable register files as a row weight on a row block-by-row block basis for row blocks generated by row-wise division of the check matrix; a first shifting step of shifting the data read; a parallel row operation step of performing a row operation in parallel on a word-by-word basis using data shifted; a second shifting step of shifting as many operational results as the row weight, obtained by the row operation, to undo the shifting; and a first update step of updating values in the intermediate value storage unit with operational results.

### CROSS-REFERENCE TO RELATED APPLICATION

This application is a continuation application of International Application PCT/JP2020/008111, filed on Feb. 27, 2020, and designating the U.S., the entire contents of which are incorporated herein by reference.

### BACKGROUND OF THE INVENTION

### 1. Field of the Invention

The present disclosure relates to a decoding method, a decoding device, a control circuit, and a program storage medium, each for decoding a low-density parity-check (LDPC) code.

### 2. Description of the Related Art

When a check matrix for an LDPC code is divisible into P×P sub-matrices (where P is an integer greater than or equal to 2), and the sub-matrices are each represented by one of a unit matrix, a quasi-unit matrix, a shift matrix, a sum matrix, and a null matrix, a decoding device that decodes that LDPC code can perform a row operation and a column operation each with a degree of parallelism of P. In this respect, a quasi-unit matrix is a matrix having at least one element, among the elements having a value of “1” in a unit matrix, being replaced with “0”; a shift matrix is a matrix obtained by cyclically shifting a unit matrix or a quasi-unit matrix; and a sum matrix is a sum of at least two matrices that are each one of a unit matrix, a quasi-unit matrix, and a shift matrix. An LDPC code having a check matrix divisible into sub-matrices each represented by one of a unit matrix, a quasi-unit matrix, a shift matrix, a sum matrix, and a null matrix is also called a quasi-cyclic (QC)-LDPC code.

Japanese Patent No. 4224777 discloses a decoding device that includes P check node calculators and P variable node calculators to perform a row operation and a column operation each with a degree of parallelism of P. The decoding device described in Japanese Patent No. 4224777 stores a value of a branch connecting between a check node and a variable node in each corresponding one of first-in first-out (FIFO) memories. The decoding device of Japanese Patent No. 4224777 then reads one value at a time, among values stored in each corresponding one of the FIFO memories, and inputs the value to the corresponding one of the check node calculators via a selector to perform a row operation with a degree of parallelism of P, and reads one value at a time, among values stored in each corresponding one of the FIFO memories, and inputs the value to the corresponding one of the variable node calculators via a selector to perform a column operation with a degree of parallelism of P. The row operation is performed by reading data from (N-K)/P FIFO memories arranged in parallel, and these FIFO memories have depths corresponding to the respective row weights of respective groups each having P rows of the check matrix. Note that N is the code length, and K is the data length of information data corresponding to one codeword of the LDPC code. In addition, the column operation is performed by reading data from N/P FIFO memories arranged in parallel, and these FIFO memories have depths corresponding to the respective column weights of respective groups each having P columns of the check matrix.

The technology described in above Japanese Patent No. 4224777 performs a row operation in which an operation is repeated for FIFO memories, of reading one value at a time, among values stored in that FIFO memory, and providing the value to the selector; and similarly, performs a column operation in which an operation is repeated for FIFO memories, of reading one value at a time, among values stored in that FIFO memory, and providing the value to the selector. Thus, in the decoding device described in Japanese Patent No. 4224777, a large row weight or a long code length requires a large number of times of reading a value from a FIFO memory in a single row operation. Similarly, a large column weight or a long code length requires a large number of times of reading a value from a FIFO memory in a single column operation. This presents a problem in requiring a time for the decoding device described in Japanese Patent No. 4224777 to perform decoding, and is therefore not suitable for high-speed transmission.

### SUMMARY OF THE INVENTION

To solve the problem and achieve the object described above, the present disclosure is directed to a decoding method to be performed by a decoding device including a storage unit that receives codewords of a low-density parity-check code having a check matrix divisible into P-row by P-column sub-matrices, and stores reception data, in which P is an integer greater than or equal to 2, and an intermediate value storage unit having as many storage areas as a number dependent on a column weight of the check matrix. The decoding method includes a storing step of reading the reception data from the storage unit in units of P words, of reproducing a piece of data read, based on the column weight of a P-column unit of the check matrix, and of writing the pieces of data generated by the reproducing, into respective corresponding ones of the storage areas in the intermediate value storage unit. The decoding method also includes a selection step of reading, on a row block-by-row block basis for row blocks generated by row-wise division of the check matrix, pieces of data from as many the storage areas as a row weight associated with that row block, in the intermediate value storage unit, and a first shifting step of shifting as many the pieces of data as the row weight that have been read in the selection step, by respective amounts corresponding to respective positions of elements having a value “1” in the check matrix, the elements corresponding to the respective storage areas that are sources of the respective pieces of data. The decoding method further includes a parallel row operation step of performing a row operation in parallel on a word-by-word basis using as many pieces of data as the row weight, obtained by the shifting performed by the first shifting step, and a second shifting step of shifting as many operational results as the row weight, obtained by the parallel row operation step, to undo the shifting performed in the first shifting step. The decoding method still further includes a first update step of updating values in corresponding ones of the storage areas in the intermediate value storage unit with as many the operational results as the row weight that have undergone the shifting performed by the second shifting step, a first control step of causing the selection step, the first shifting step, the parallel row operation step, the second shifting step, and the first update step to be performed for all the row blocks, and a column operation step of performing a column operation using values stored in the respective storage areas in the intermediate value storage unit after performing the first control step.

### BRIEF DESCRIPTION OF THE DRAWINGS

FIG. 1 is a diagram illustrating an example functional configuration of a decoding device according to a first embodiment;

FIG. 2 is a flowchart illustrating an example of decoding procedure performed by the decoding device of the first embodiment;

FIG. 3 is a flowchart illustrating an example of row operation procedure performed in the decoding device of the first embodiment;

FIG. 4 is a flowchart illustrating an example of column operation procedure performed in the decoding device of the first embodiment;

FIG. 5 is a diagram illustrating an example configuration of a processing circuitry in a case in which the decoding device of the first embodiment is implemented by a dedicated hardware element;

FIG. 6 is a diagram illustrating an example configuration of a control circuit in a case in which the decoding device of the first embodiment is implemented by the control circuit; and

FIG. 7 is a diagram illustrating an example functional configuration of a decoding device according to a second embodiment.

### DETAILED DESCRIPTION OF THE PREFERRED EMBODIMENTS

A decoding method, a decoding device, a control circuit, and a program storage medium according to embodiments will be described in detail below with reference to the drawings. Note that the embodiments are not intended to suggest any limitation.

### First Embodiment

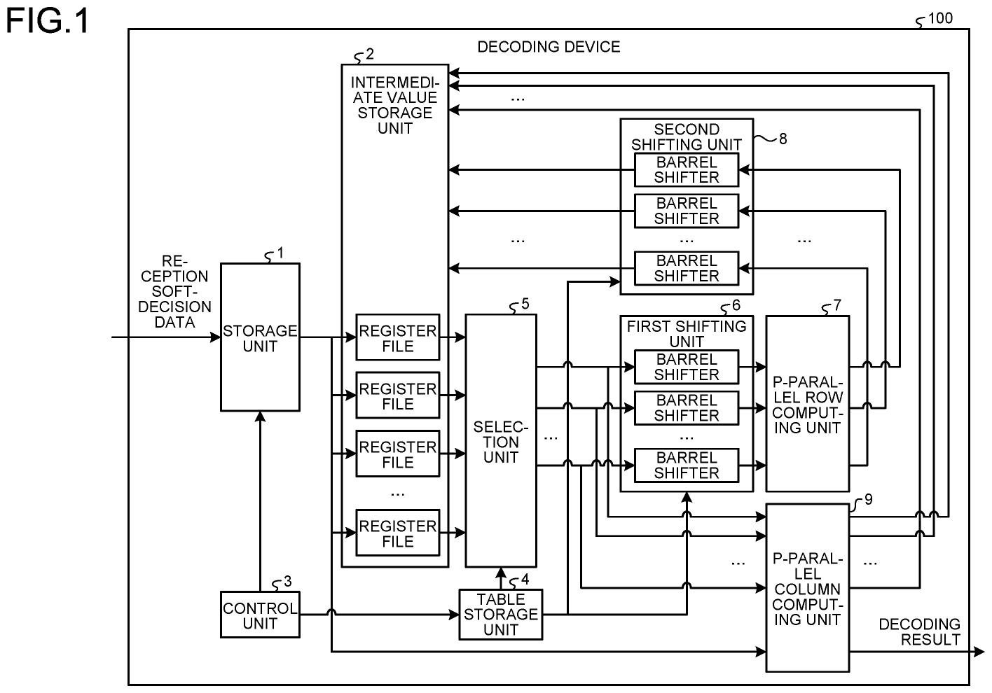

FIG. 1 is a diagram illustrating an example functional configuration of a decoding device according to a first embodiment. A decoding device 100 of the present embodiment receives codewords of a low-density parity-check code (LDPC code) generated by an encoder not illustrated, and decodes received words, i.e., reception data. Note that the term “reception” or “to receive” refers not only to reception of reception data from another device, but also to reception of reception data from another component of a same device. As illustrated in FIG. 1, the decoding device 100 of the present embodiment includes a storage unit 1, an intermediate value storage unit 2, a control unit 3, a table storage unit 4, a selection unit 5, a first shifting unit 6, a P-parallel row computing unit 7, a second shifting unit 8, and a P-parallel column computing unit 9.

The decoding device 100 of the present embodiment is installed, for example, in a communication device that communicates wirelessly or through a wired connection. For example, the decoding device 100 is installed in a reception device that is a communication device receiving a signal. This reception device receives, from a transmission device, a signal containing codewords of an LDPC code generated in the transmission device, converts that signal into a digital signal, and inputs, to the decoding device 100, the digital signal, i.e., a reception signal itself, or a result of processing such as soft decision demodulation, which provides a soft decision result in response to the reception signal, as reception soft-decision data. The following description may refer to this reception soft-decision data as reception data. Note that the device that incorporates the decoding device 100 is not limited to a communication device, but the decoding device 100 may be installed in any device that is to perform error correction operation.

The present embodiment assumes that a check matrix for an LDPC code is divisible into P×P (i.e., P-row by P-column) sub-matrices, which are each represented by one of a unit matrix, a quasi-unit matrix, a shift matrix, a sum matrix, and a null matrix, where P is an integer greater than or equal to 2.

Functionality of each component included in the decoding device 100 illustrated in FIG. 1 will next be described. The storage unit 1 stores reception soft-decision data that has been input to the decoding device 100. The intermediate value storage unit 2 includes multiple register files, which are multiple storage areas. The multiple register files are an example of multiple simultaneously accessible storage areas. In more detail, the intermediate value storage unit 2 includes, as described later, as many register files as, for example, a number dependent on the column weights of the check matrix. The register files each store a corresponding portion of the reception soft-decision data stored in the storage unit 1 as an initial value, and the data stored therein is updated during the process of decoding. The control unit 3 controls the operation of the decoding device 100. Note that it is assumed here that the check matrix that has been used in encoding the LDPC code is preset in, or provided in notification to, the decoding device 100, and the control unit 3 holds the check matrix or information representing the check matrix. Note that the check matrix or the information representing the check matrix may be stored in the table storage unit 4.

The table storage unit 4 stores a table for use by the control unit 3 to control processes. Contents of this table are written by the control unit 3. The table includes, for example, information indicating which of a row operation and a column operation is currently being performed, information indicating data to be read by the selection unit 5 from the intermediate value storage unit 2, information representing the number of shift stages used in a shift operation in each of the first shifting unit 6 and the second shifting unit 8, and the like.

In a row operation, the selection unit 5 selects, on a row block-by-row block basis for the row blocks generated by row-wise division of the check matrix, as many register files as the row weight of a unit having P rows (hereinafter, P-row unit) associated with that row block, from the multiple register files in the intermediate value storage unit 2, based on the table included in the table storage unit 4, reads data from the register files selected, and outputs the data to the first shifting unit 6. In a column operation, the selection unit 5 selects and reads data according to the column weight of each unit having P columns (hereinafter, P-column unit) from the multiple register files in the intermediate value storage unit 2 based on the table included in the table storage unit 4, and outputs the data to the first shifting unit 6.

The first shifting unit 6 shifts as many pieces of data as the row weight, read by the selection unit 5, by respective amounts corresponding to the respective positions of elements having a value “1” in the check matrix, where the elements correspond to the respective register files that are the sources of the respective pieces of data. For example, the first shifting unit 6 includes multiple barrel shifters. The pieces of data output from the selection unit 5 are input to the respective barrel shifters. The barrel shifters each perform a cyclic shift operation by the number of stages specified in the table based on the table included in the table storage unit 4, and input cyclically shifted data to the P-parallel row computing unit 7.

The P-parallel row computing unit 7 is a parallel row computing unit that performs a row operation in parallel on a word-by-word basis using as many pieces of data as the row weight, obtained by the shift operation performed by the first shifting unit 6. Specifically, the P-parallel row computing unit 7 performs a row operation according to an LDPC-code decoding algorithm with a degree of parallelism of P, and outputs multiple pieces of data obtained by the row operation to the second shifting unit 8.

The second shifting unit 8 shifts as many operational results as the row weight, obtained by the P-parallel row computing unit 7, to undo the shift operation performed in the first shifting unit 6. The second shifting unit 8 includes multiple barrel shifters. The pieces of data output from the P-parallel row computing unit 7 are input to the respective barrel shifters. The multiple barrel shifters of the second shifting unit 8 perform a cyclic shift operation to undo the shift operations performed by the respective barrel shifters of the first shifting unit 6. The pieces of data in the multiple register files in the intermediate value storage unit 2 are respectively updated with the pieces of data obtained by the cyclic shift operation performed by the multiple barrel shifters of the second shifting unit 8.

The P-parallel column computing unit 9 is a parallel column computing unit that performs a column operation after the row operation, using the values stored in the register files in the intermediate value storage unit 2. In more detail, the P-parallel column computing unit 9 performs an addition operation of data read from the applicable register files in the intermediate value storage unit 2 with a degree of parallelism of P. The P-parallel column computing unit 9 outputs the result of the addition operation as the decoding result at the last iteration. During the iterative process, the P-parallel column computing unit 9 subtracts its own value from the result of the addition operation, and updates the data in the multiple register files in the intermediate value storage unit 2 with the respective subtraction results.

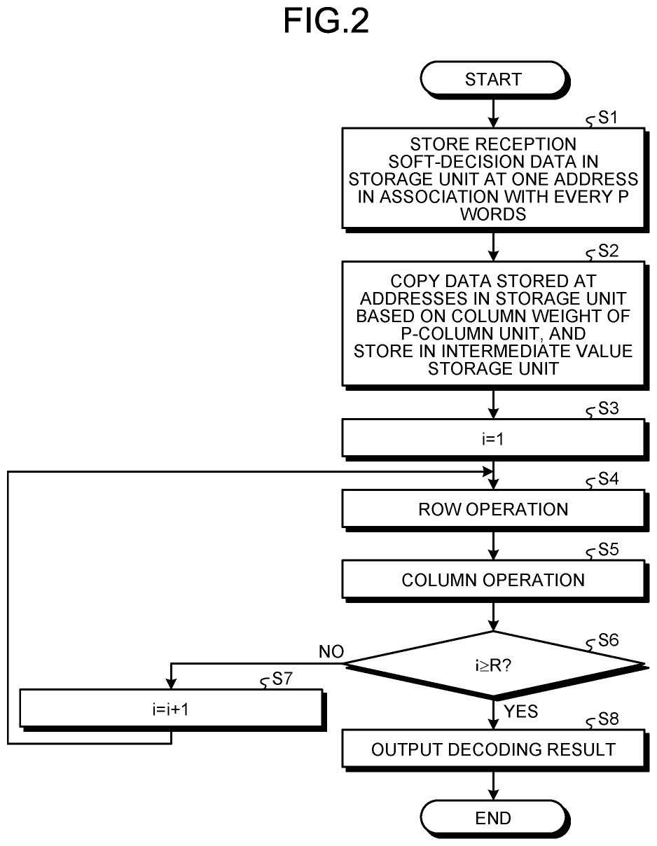

A decoding method performed by the decoding device 100 of the present embodiment will next be described. FIG. 2 is a flowchart illustrating an example of decoding procedure performed by the decoding device 100 of the present embodiment. As illustrated in FIG. 2, the decoding device 100 stores the reception soft-decision data in the storage unit 1 at one address in association with every P words (step S1). In more detail, the control unit 3 stores the reception soft-decision data in the storage unit 1 at one address of the storage unit 1 in association with every P words. As used herein, a word is a unit of data quantity with respect to the reception soft-decision data, and corresponds, for example, to a reception log likelihood ratio (LLR) (in multiple bits) corresponding to one transmission bit. The data quantity equivalent to one address is therefore P×W bits when one word has W bits (where W is an integer greater than or equal to 1).

The LDPC code has a code length of N words, where N is the number of columns of the check matrix for the LDPC code. As described above, the LDPC code is divisible into P×P sub-matrices in the present embodiment. The number N of columns and the number of rows of the check matrix are each a multiple of P. Assume that the number N of columns of the check matrix is a product of P and B_{C}, and the number of rows (N-K) of the check matrix is a product of P and B_{R}, where B_{C} and B_{R} are each an integer greater than or equal to 2. The following description will be provided with respect to an example of when B_{C}=8 and B_{R}=5, but B_{C} and B_{R} are not limited to these values.

At step S1, a one-code length portion of the reception soft-decision data is divided into portions each having P words (hereinafter, P-word portions), and the P-word portions of the reception soft-decision data are stored in respective areas associated with respective different addresses. For example, when B_{C}=8, the P-word portions of the reception soft-decision data are stored in eight respective areas in the storage unit 1, associated with eight respective addresses from address #0 to address #7. Note that the address values associated with the respective portions of data are not limited to those of this example.

Next, the decoding device 100 copies a piece of data stored at each applicable address in the storage unit 1, based on the column weight of each P-column unit, and stores the copies in the intermediate value storage unit 2 (step S2). That is, step S2 is a storing step of reading the reception data from the storage unit 1 in units of P words, of reproducing a piece of the data read, based on the column weight of each P-column unit of the check matrix, and of writing pieces of data generated by the reproducing, into respective corresponding ones of the register files in the intermediate value storage unit 2. In more detail, the control unit 3 reads a piece of data associated with each applicable address stored in the storage unit 1 on an address-by-address basis, copies the piece of data based on the column weight of each P-column unit associated with that address, of the check matrix, and stores the pieces of data generated by copying, to the respective different register files in the intermediate value storage unit 2. When N=8P, the column weights of the respective P-column units are given by eight values. That is, the control unit 3 provides control to cause the reception data to be read from the storage unit 1 in units of P words, to cause the data read, to be reproduced based on the column weight of each P-column unit of the check matrix, and to cause the pieces of data generated by the reproduction to be written into the corresponding ones of the register files in the intermediate value storage unit 2.

In this operation, the column weights of the respective P-column units associated with respective addresses #0 to #7 are assumed to be {8, 3, 3, 3, 2, 2, 2, 2}. In this case, the control unit 3 controls the storage unit 1 and the intermediate value storage unit 2 to cause the P words of data stored in the area at address #0 of the storage unit 1 to be written into eight, zero-th to seventh, register files in the intermediate value storage unit 2. The control unit 3 also provides control to cause the data stored at address #1 of the storage unit 1 to be written into eighth through tenth register files in the intermediate value storage unit 2. Similarly, the control unit 3 provides control to cause the data stored at address #2 of the storage unit 1 to be written into eleventh through thirteenth register files in the intermediate value storage unit 2, and provides control to cause the data stored at address #3 of the storage unit 1 to be written into fourteenth through sixteenth register files in the intermediate value storage unit 2. The control unit 3 further provides control to cause the data stored at address #4 of the storage unit 1 to be written into seventeenth and eighteenth register files in the intermediate value storage unit 2, and provides control to cause the data stored at address #5 of the storage unit 1 to be written into nineteenth and twentieth register files in the intermediate value storage unit 2. The control unit 3 still further provides control to cause the data stored at address #6 of the storage unit 1 to be written into 21st and 22nd register files in the intermediate value storage unit 2, and provides control to cause the data stored at address #7 of the storage unit 1 to be written into 23rd and 24th register files in the intermediate value storage unit 2. The data are thus written into the zero-th through 24th, 25 in total, register files in the intermediate value storage unit 2. Thus, the intermediate value storage unit 2 includes at least 25 register files, correspondingly to the sum of the column weights.

Next, the control unit 3 sets a variable “i” to “1”, where “i” represents the number of iterations in decoding (step S3), and performs a row operation (step S4) and a column operation (step S5). The row operation and the column operation will be described later in detail. The control unit 3 determines whether the variable “i” is greater than or equal to R, where R is the maximum number of iterations in decoding (step S6). If the variable “i” is less than R (No at step S6), the control unit 3 updates the variable “i” as i=i+1 (step S7), and repeats the process from step S4. If the variable “i” is greater than or equal to R (Yes at step S6), the decoding device 100 outputs a decoding result (step S8), and terminates the process.

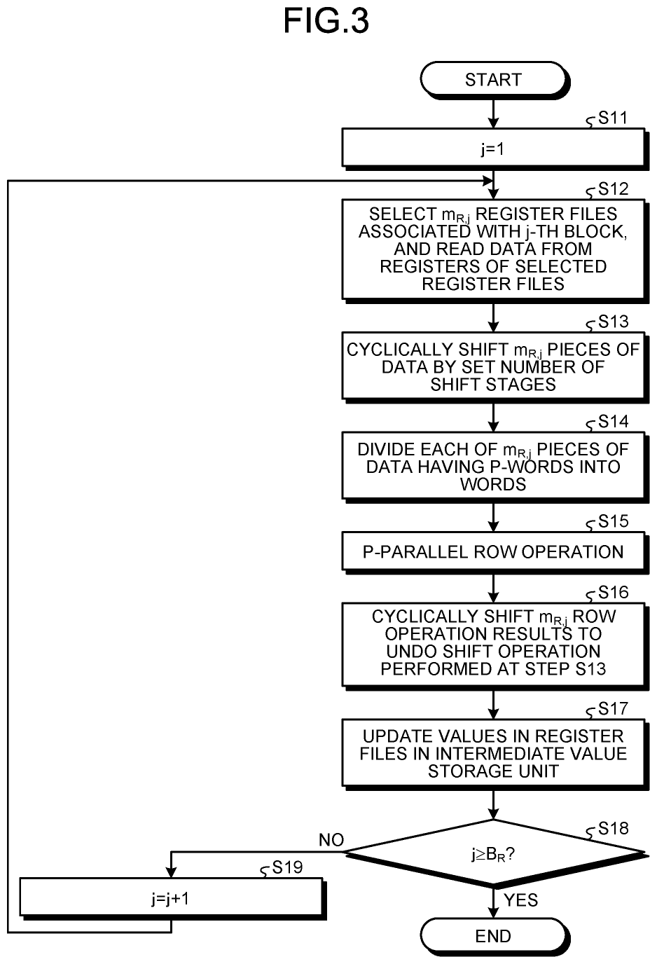

The row operation at step S4 described above will next be described. FIG. 3 is a flowchart illustrating an example of row operation procedure performed in the decoding device 100 of the present embodiment. The present embodiment assumes that one set of row operation is performed on each of B_{R} blocks. These blocks are results of dividing the N rows of the check matrix into P-row units.

As illustrated in FIG. 3, the control unit 3 of the decoding device 100 first sets a variable “j” to “1”, where the variable “j” identifies a block (row block) (step S11). The decoding device 100 selects m_{R,j} register files associated with a j-th block, which is the block at a j-th position row-wise, and then reads data from the registers in the register files selected (step S12). The value m_{R,j} is the row weight of the P-row unit, of the row-wise j-th block. In more detail, at step S12, the control unit 3 of the decoding device 100 stores, in the table in the table storage unit 4, information indicating that a row operation is currently being performed, and information (register selection information) representing the m_{R,j} register files to be selected in the process for the j-th block among the 25 register files. The selection unit 5 selects the m_{R,j} register files associated with the j-th block based on the register selection information in the table, and reads data from the registers in the register files selected. Note that these 25 register files correspond to respective elements being elements having a value “1” in the check matrix. Accordingly, previously associating the positions of the elements having a value “1” in the check matrix with the respective register file numbers predetermines which register files to select in processing of each block, i.e., the register selection information.

Note that instead of writing the register selection information into the table, an operation may be performed in which the register selection information for all the blocks is stored in the table in the table storage unit 4 on a per-block basis, and the control unit 3 writes, into the table, information indicating which block is being processed, i.e., the value of “j”, to allow the selection unit 5 to extract the register selection information for the j-th block based on these pieces of information. Thus, the table stores B_{R} row weights, i.e., m_{R,1} to m_{R,BR}, where m_{R,j} represents the row weight of the j-th block, and the subscript BR in m_{R,BR} represents B_{R}.

After step S12, the selection unit 5 inputs the data read, to the first shifting unit 6, causing the first shifting unit 6 to cyclically shift the m_{R,j} pieces of data by the set number of shift stages (step S13). For example, when the row weights are {6, 5, 5, 5, 4}, processing relating to the first block is performed such that pieces of data are read from six respective register files among the 25 register files, and the six pieces of data are input to six respective barrel shifters of the first shifting unit 6. The six barrel shifters each perform a cyclic shift operation by the number of stages specified in the table in the table storage unit 4. Processing relating to each of the second through fourth blocks is performed such that pieces of data are read from five respective register files among the 25 register files, and the five pieces of data are input to five respective barrel shifters of the first shifting unit 6. Processing relating to the fifth block is performed such that pieces of data are read from four respective register files among the 25 register files, and the four pieces of data are input to four respective barrel shifters of the first shifting unit 6. The shift amount, i.e., the number of shift stages, of each of the barrel shifters is determined based on the corresponding position corresponding to that register file, in the check matrix. For processing relating to the i-th block, the m_{R,j} barrel shifters use cyclic shift operation, and therefore, shift amounts k₁, . . . , and kₘ are stored in the table in the table storage unit 4, where m_{R,j} is written here as m for simplicity.

Step S12 is a selection step of reading pieces of data from as many register files as the row weight associated with that row block, in the intermediate value storage unit 2, on a row block-by-row block basis for the row blocks generated by row-wise division of the check matrix. In addition, step S13 is a first shifting step of shifting as many the pieces of data read as the row weight by respective amounts corresponding to the respective positions of elements having a value “1” in the check matrix, where the elements correspond to the respective register files that are sources of the respective pieces of data.

After step S13, the first shifting unit 6 divides each of the m_{R,j} pieces of data having P words into words (step S14). The pieces of data generated by the division are parallelized into a P-parallel form, and are input to the P-parallel row computing unit 7. The P-parallel row computing unit 7 performs a P-parallel row operation (step S15). The m_{R,j} pieces of data are together input to the corresponding one of P-parallel computing units. That is, the P-parallel row computing unit 7 receives the m_{R,j} pieces of data at one time.

The P-parallel row computing unit 7 performs a row operation according to an LPDC-code decoding algorithm. Examples of this decoding algorithm include generally used algorithms, such as min-sum algorithm and offset min-sum algorithm. The P-parallel row computing unit 7 inputs m_{R,j} processing results of the row operation to the respective m_{R,j} barrel shifters of the second shifting unit 8.

The second shifting unit 8 cyclically shifts the m_{R,j} row operation results to undo the shift operation performed at step S13 (step S16). Specifically, the barrel shifters of the second shifting unit 8 each perform a cyclic shift operation by an amount of (P-S) stages, where S represents the number of stages shifted by each corresponding one of the barrel shifters of the first shifting unit 6.

The second shifting unit 8 updates the values in the respective applicable register files in the intermediate value storage unit 2 with the cyclically shifted data, under control of the control unit 3 (step S17). In more detail, the second shifting unit 8 inputs the m_{R,j} pieces of data to the intermediate value storage unit 2, and the intermediate value storage unit 2 updates, under control of the control unit 3, the values in the respective m_{R,j} register files selected, for reading, by the selection unit 5 at step S12, with the respective m_{R,j} pieces of data input. That is, the control unit 3 provides control to cause the values in the corresponding register files in the intermediate value storage unit 2 to be updated with the as many operational results as the row weight that have undergone the shift operation performed by the second shifting unit 8. Step S15 is a parallel row operation step, and step S16 is a second shifting step of shifting as many operational results as the row weight, obtained by the parallel row operation step, to undo the shift operation performed by the first shifting unit 6. Step S17 is a first update step of updating the values in the corresponding register files in the intermediate value storage unit 2, with the as many operational results as the row weight that have undergone the shifting performed by the second shifting step.

Next, the control unit 3 determines whether the variable “j” is greater than or equal to B_{R} (step S18). If the variable “j” is less than B_{R} (No at step S18), the control unit 3 updates “j” as j=j+1 (step S19), and provides control to perform the process again from step S12. That is, the control unit 3 performs a first control step, in which the control unit 3 causes the selection step, the first shifting step, the parallel row operation step, the second shifting step, and the first update step to be performed for all the row blocks. If the variable “j” is greater than or equal to B_{R} (Yes at step S18), the control unit 3 terminates the row operation.

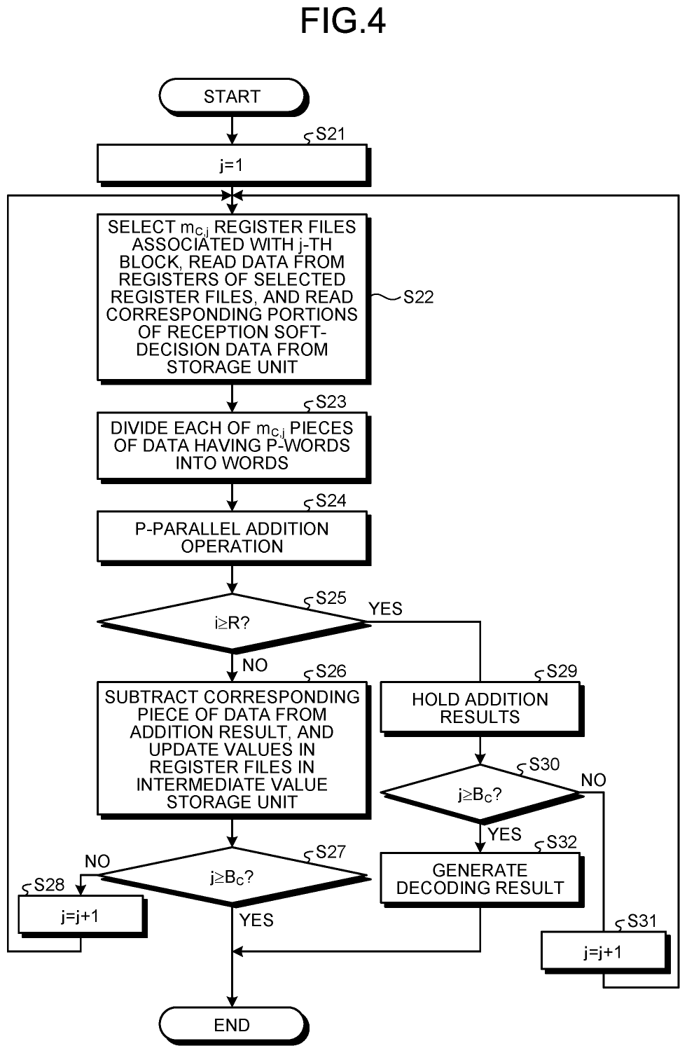

The column operation at step S5 described above will next be described. FIG. 4 is a flowchart illustrating an example of column operation procedure performed in the decoding device 100 of the present embodiment. The present embodiment assumes that one set of column operation is performed on each of B_{C} blocks. These blocks are results of dividing the N columns of the check matrix into P-column units.

As illustrated in FIG. 4, the control unit 3 of the decoding device 100 first sets a variable “j” to “1”, where the variable “j” identifies a block (column block) (step S21). The decoding device 100 selects m_{C,j} register files associated with a j-th block, which is the block at a j-th position column-wise, reads data from the registers in the register files selected, and reads corresponding portions of the reception soft-decision data from the storage unit 1 (step S22). The value m_{C,j} is the column weight (block column weight), and specifically the column weight of the P-column unit, of the column-wise j-th block. In more detail, at step S22, the control unit 3 of the decoding device 100 stores, in the table in the table storage unit 4, information indicating that a column operation is currently being performed, and information (register selection information) representing the m_{C,j} register files to be selected in the process for the j-th block among the 25 register files. The selection unit 5 selects the m_{C,j} register files associated with the j-th block based on the register selection information in the table, and reads data from the registers in the register files selected. Step S22 is a read step of reading data from as many register files as the block column weight associated with that column block, in the intermediate value storage unit 2, on a column block-by-column block basis for the column blocks generated by column-wise division of the check matrix. In addition, under control of the control unit 3, data stored at address #(j-1) associated with the j-th block, of the reception soft-decision data is read from the storage unit 1, is parallelized into a P-parallel form, and is input to the P-parallel column computing unit 9.

The selection unit 5 divides each of the m_{C,j} pieces of data having P words into words (step S23). The pieces of data generated by the division are parallelized into a P-parallel form, and are input to the P-parallel column computing unit 9. The P-parallel column computing unit 9 performs a P-parallel column operation, i.e., a P-parallel addition operation, based on the data input from the selection unit 5 and on the data input from the storage unit 1 (step S24). In more detail, the P-parallel column computing unit 9 calculates a sum Y+X₀+X₁+ . . . +X_{M-1} as X_{SUM}, and subtracts X₀, X₁, . . . , and X_{M-1} from X_{SUM} to obtain respective differences thus to generate P sets of the differences, where Y is the reception soft-decision data, M is the number of pieces of data input from the intermediate value storage unit 2, and X₀ to X_{M-1} are the respective pieces of data read from the intermediate value storage unit 2. Step S24 is a parallel column operation step of performing a column operation in parallel on a word-by-word basis using the as many pieces of data as the block column weight, read by the read step, and using the reception data.

The decoding device 100 determines whether the variable “i” is greater than or equal to R (step S25), and if the variable “i” is greater than or equal to R (Yes at step S25), holds the addition results of respective P-parallel operations (step S29). In more detail, the control unit 3 determines whether the variable “i” is greater than or equal to R, and stores the determination result in the table in the table storage unit 4, and the P-parallel column computing unit 9 reads this determination result from the table to identify whether the variable “i” is greater than or equal to R. If the variable “i” is greater than or equal to R, the addition result is held. The decoding device 100 further determines whether the variable “j” is greater than or equal to B_{C} (step S30), and if the variable “j” is greater than or equal to B_{C} (Yes at step S30), generates a decoding result based on the addition results held for the respective blocks, outputs the decoding result (step S32), and terminates the column operation. In more detail, the control unit 3 determines whether the variable “j” is greater than or equal to B_{C}, and if the variable “j” is greater than or equal to B_{C}, writes the determination result, i.e., information indicating that the variable “j” is greater than or equal to B_{C} into the table in the table storage unit 4, and the P-parallel column computing unit 9 reads this information from the table to identify that the variable “j” is greater than or equal to B_{C}, and if the variable “j” is greater than or equal to B_{C}, generates and outputs the decoding result.

If the variable “j” is less than B_{C} (No at step S30), the control unit 3 of the decoding device 100 updates the variable “j” as j=j+1 (step S31), and provides control to repeat the process from step S22. In addition, if the variable “i” is less than R at step S25 (No at step S25), the decoding device 100 subtracts the value of the corresponding piece of data, i.e., the value of its own data, from the addition result, and updates the values in the respective corresponding register files in the intermediate value storage unit 2 (step S26). In more detail, the control unit 3 determines whether the variable “i” is greater than or equal to R, and stores the determination result in the table in the table storage unit 4, and the P-parallel column computing unit 9 reads this determination result from the table to identify that the variable “i” is less than R. If the variable “i” is less than R, the P-parallel column computing unit 9 subtracts the value of its own data from the addition result, and updates the values in the respective corresponding register files among the register files in the intermediate value storage unit 2. Step S26 is a second update step of updating the values of the corresponding register files in the intermediate value storage unit 2, with as many operational results as the block column weight, obtained by the parallel column operation step.

After step S26, it is determined, similarly to step S30, whether the variable “j” is greater than or equal to B_{C} (step S27), and if the variable “j” is greater than or equal to B_{C} (Yes at step S27), the decoding device 100 terminates the column operation. If the variable “j” is less than B_{C} (No at step S27), the control unit 3 of the decoding device 100 updates the variable “j” as j=j+1 (step S28), and provides control to repeat the process from step S22. As described above, the control unit 3 causes a second control step to be performed to cause the read step, the parallel column operation step, and the second update step to be performed for all the column blocks.

Note that the foregoing description has been given of a configuration in which the control unit 3 delivers information to components via the table in the table storage unit 4, but may directly notify the components of one or more parts of the information.

The foregoing processes significantly reduce the number of processing steps required for the row operation calculation and for the column operation calculation as compared to a conventional technology that uses a FIFO memory. This enables the decoding device 100 of the present embodiment to provide decoding of an LDPC code that also supports high transmission speed.

In addition, the foregoing example assumes that calculation in the row operation and in the column operation is performed by selecting register files sequentially beginning from the first one row-wise and column-wise in the check matrix based on the row weight or the column weight. However, the order of calculation is not limited to the sequential order beginning from the first one, but may be any order. Calculation in an order different from the order of the foregoing example also provides an advantage similar to the advantage of the foregoing example.

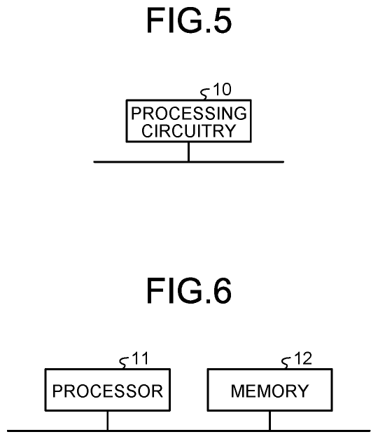

A hardware configuration of the decoding device 100 will next be described. The storage unit 1, the intermediate value storage unit 2, the control unit 3, the table storage unit 4, the selection unit 5, the first shifting unit 6, the P-parallel row computing unit 7, the second shifting unit 8, and the P-parallel column computing unit 9 of the decoding device 100 are implemented in a processing circuitry. The processing circuitry may be a dedicated hardware element, or a control circuit including a processor. FIG. 5 is a diagram illustrating an example configuration of the processing circuitry in a case in which the decoding device 100 of the present embodiment is implemented by a dedicated hardware element.

A processing circuitry 10 illustrated in FIG. 5 is, for example, a single circuit, a set of multiple circuits, a programmed processor, a parallel programmed processor, a field programmable gate array (FPGA), an application specific integrated circuit (ASIC), or a combination thereof. The functionalities of the storage unit 1, the intermediate value storage unit 2, the control unit 3, the table storage unit 4, the selection unit 5, the first shifting unit 6, the P-parallel row computing unit 7, the second shifting unit 8, and the P-parallel column computing unit 9 may be implemented in different processing circuitries, or two or more of these functionalities may together be implemented in the processing circuitry 10.

FIG. 6 is a diagram illustrating an example configuration of the control circuit in a case in which the decoding device 100 of the present embodiment is implemented by the control circuit. As illustrated in FIG. 6, the control circuit includes a processor 11 and a memory 12. The processor 11 is a central processing unit (CPU), a digital signal processor (DSP), or the like, and the memory 12 is a non-volatile or volatile semiconductor memory such as a random access memory (RAM), a read-only memory (ROM), a flash memory, an erasable programmable read-only memory (EPROM), or an electrically erasable programmable read-only memory (EEPROM) (registered trademark); a magnetic disk, a flexible disk, an optical disk, a compact disc, a digital versatile disc (DVD), or the like.

In a case in which the decoding device 100 is implemented by a control circuit, the functionality of each component of the decoding device 100 is implemented in software, firmware, or a combination of software and firmware. The software and/or firmware is described as a program, and the program stored in the memory 12 is read and executed by the processor 11 to implement the functionality of each component of the decoding device 100. This program may be delivered via a storage medium, i.e., a program storage medium, or via a transmission medium. It can also be said that this program is a program that causes the decoding device 100, which is a computer, to perform the processing steps to be performed by the decoding device 100. When the decoding device 100 is installed in a communication device, this control circuit is a control circuit for controlling the communication device, and causes the communication device to perform the processing steps to be performed by the decoding device 100. In addition, in this case, the program storage medium stores a program for controlling the communication device by causing the communication device to perform the processing steps to be performed by the communication device incorporating the decoding device 100.

In addition, part of the components included in the decoding device 100 may be implemented in a dedicated hardware element serving as a processing circuitry, and the remainder of the components may be implemented in a control circuit. Thus, the processing circuitry can implement the foregoing functionalities in hardware, software, firmware, or a combination thereof. For example, the decoding device 100 may be implemented by a combination of a dedicated hardware element serving as a processing circuitry and a control circuit such that the P-parallel row computing unit 7 and the P-parallel column computing unit 9 are implemented in a dedicated hardware element serving as a processing circuitry, and the other components are implemented in a control circuit.

The decoding device 100 of the present embodiment includes the intermediate value storage unit 2 including multiple register files. The multiple register files store the reception soft-decision data in units of P words, and pieces of data selected according to the row weight are input from multiple register files to multiple barrel shifters of the first shifting unit 6. The pieces of data are shifted by the respective multiple barrel shifters, and then parallelized, and the results are input to the P-parallel row computing unit 7. The operational results of the P-parallel row computing unit 7 are input to respective corresponding multiple barrel shifters of the second shifting unit 8. The pieces of data input to the respective multiple barrel shifters of the second shifting unit 8 are processed, by the respective multiple barrel shifters of the second shifting unit 8, to undo the shift operation performed in the first shifting unit 6, and the values in the respective applicable register files in the intermediate value storage unit 2 are updated with the respective pieces of data output from the corresponding multiple barrel shifters of the second shifting unit 8. This enables the decoding device 100 to significantly reduce the number of processing steps required for the row operation calculation as compared to a conventional technology that uses a FIFO memory.

Moreover, in the decoding device 100 of the present embodiment, pieces of data selected according to the column weight from multiple register files, and the reception soft-decision data, are input to the P-parallel column computing unit 9, and the values in the respective applicable register files in the intermediate value storage unit 2 are updated with respective operational results of the P-parallel column computing unit 9. This enables the decoding device 100 to significantly reduce the number of processing steps required for the column operation calculation as compared to a conventional technology that uses a FIFO memory. Thus, the decoding device 100 of the present embodiment can provide decoding of an LDPC code that also supports high transmission speed.

### Second Embodiment

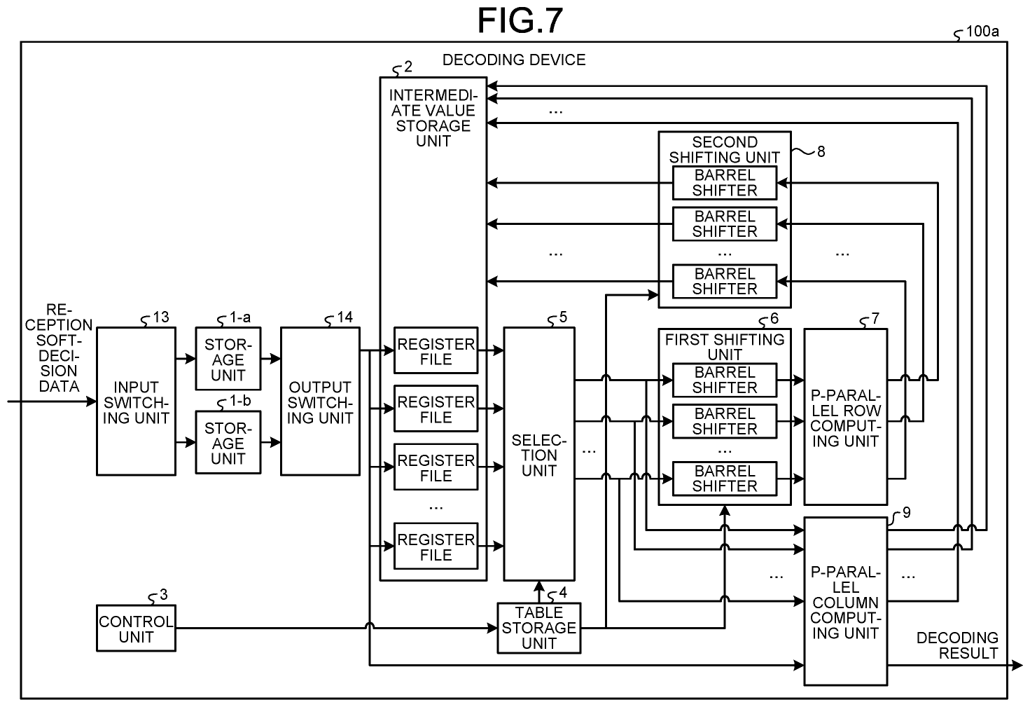

FIG. 7 is a diagram illustrating an example functional configuration of a decoding device according to a second embodiment. A decoding device 100a of the present embodiment includes an input switching unit 13 and an output switching unit 14 in addition to the components included in the decoding device 100 of the first embodiment. In addition, the decoding device 100a of the present embodiment includes storage units 1-a and 1-b in place of the storage unit 1. In other words, the storage unit of the present embodiment includes the storage unit 1-a, which is a first storage unit, and the storage unit 1-b, which is a second storage unit. The other part of the configuration of the decoding device 100a of the present embodiment is similar to the corresponding part of the configuration of the decoding device 100 of the first embodiment. Components having functionality similar to the functionality of the first embodiment are designated by the same reference characters as those of the first embodiment, and duplicate description thereof will be omitted. The following description will primarily describe differences from the first embodiment.

An operation of the decoding device 100a of the present embodiment will next be described. The storage units 1-a and 1-b are each configured similarly to the storage unit 1 of the first embodiment. In the present embodiment, the reception soft-decision data is input to the input switching unit 13, and the input switching unit 13 switches, under control of the control unit 3, the storage destination of the reception soft-decision data between the storage unit 1-a and the storage unit 1-b on a per-codeword basis. For example, the control unit 3 instructs the input switching unit 13 to write the first codeword of the soft-decision data into the storage unit 1-a. Next, upon completion of inputting of the entire one codeword of the reception soft-decision data, the control unit 3 instructs the input switching unit 13 to switch the storage unit to another as the destination for outputting, i.e., for storing, the data, thereby causing the reception soft-decision data to be written into the storage unit 1-b. The procedure of writing data into the storage unit 1-a and of writing data into the storage unit 1-b is similar to that of the first embodiment.

Upon completion of writing the one codeword into the storage unit 1-a, the control unit 3 instructs the output switching unit 14 to read the data stored in the storage unit 1-a. This allows the decoding device 100a to read, and to perform decoding of, the codeword of the reception soft-decision data already stored in the storage unit 1-a while another codeword of the reception soft-decision data is being written into the storage unit 1-b. Similarly, upon completion of writing the one codeword of the reception soft-decision data into the storage unit 1-b, the control unit 3 instructs the input switching unit 13 to switch the output destination of data to the storage unit 1-a, and also instructs the output switching unit 14 to read the data stored in the storage unit 1-b. This allows the decoding device 100a to read, and to perform decoding of, the codeword of the reception soft-decision data already stored in the storage unit 1-b while another codeword of the reception soft-decision data is being written into the storage unit 1-a. The decoding process is similar to the decoding process of the first embodiment.

As described above, the decoding method performed by the decoding device 100a of the present embodiment includes a first writing step of writing one codeword of the reception data into the storage unit 1-a, and a switching step of, upon completion of writing of the one codeword of the reception data into the storage unit 1-a, switching the destination of writing the reception data to the storage unit 1-b. In addition, this decoding method performs a decoding process described in relation to the first embodiment using the portion of the reception data stored in the storage unit 1-a while the reception data is being written into the storage unit 1-b.

The components of the decoding device 100a of the present embodiment may be implemented, similarly to the decoding device 100 of the first embodiment, by a dedicated hardware element serving as a processing circuitry, by the control circuit described in relation to the first embodiment, or by a combination thereof.

As described above, the decoding device 100a of the present embodiment includes two storage units, which are the storage units 1-a and 1-b, and the storage destination of the reception soft-decision data is switched between these two storage units. This enables simultaneous performance of the operation of writing the reception soft-decision data and the process of decoding the reception soft-decision data of a portion corresponding to a code immediately before the code being currently written. This enables the decoding device 100a of the present embodiment to provide an advantage similar to the advantage of the first embodiment, and to achieve a higher speed of processing than the speed achieved by the decoding device 100 of the first embodiment.

### Third Embodiment

An operation of a decoding device of a third embodiment will next be described. The decoding device of the present embodiment is configured similarly to the decoding device 100 of the first embodiment or to the decoding device 100a of the second embodiment. The following description describes an example in which the decoding device of the present embodiment is configured similarly to the decoding device 100 of the first embodiment.

The first embodiment has been described with respect to an example in which, in the row operation, data is read from as many register files as the row weight of the corresponding P-row unit of the check matrix, among the multiple register files in the intermediate value storage unit 2. That is, in the first embodiment, (N-K) rows of the check matrix are divided into (N-K)/P blocks each having P rows, and data is read from corresponding register files on a per-block basis. In the present embodiment, the number of rows of a row-wise block is not fixed to P, but is defined as PλX, where X is an integer greater than or equal to 1. Thus, the numbers of rows of the respective multiple row blocks generated by row-wise division of the check matrix are each X×P, where the value of X depends on the row blocks.

For example, a first block is associated with P rows, and a second block and a third block are each associated with 2P rows. Assume, for example, that the row weights of the respective P-row units are {6, 5, 5, 5, 4}. The row weight (block row weight) of the first block is 6, the row weight of the second block is 10, and the row weight of the third block is 9. The blocks are defined in this manner, and based on this definition, the register files to be selected for the blocks are defined in a form of a table. This results in, at step S12 of FIG. 3, a process for the first block to select six register files, a process for the second block to select ten register files, and a process for the third block to select nine register files. In this case, the value of B_{R} is 3. Thus, one row operation is performed on the three divided blocks.

As described above, the method of division into row-wise blocks (row blocks) is different from that of the first embodiment. This may result in a value of the row weight associated with a block, different from the corresponding value in the first embodiment even when a same check matrix is used, but otherwise the row operation in the present embodiment is similar to the row operation in the first embodiment.

The present embodiment can reduce the number of divided blocks to be processed in the row operation as compared to that in the first embodiment, and can thus reduce the number of processing steps required for the decoding process. The present embodiment can accordingly further increase the speed of the decoding process as compared to the first embodiment. Note that an example has been described above in which the decoding device 100 of the first embodiment uses a method of division into blocks different from the method used in the first embodiment. However, the decoding device 100a of the second embodiment may also perform the decoding process using the different method of division into blocks, that is, using a definition of (P×X) rows as one block for performing the foregoing operation. This can further increase the speed of the decoding process as compared to the decoding device 100a of the second embodiment.

### Fourth Embodiment

An operation of a decoding device of a fourth embodiment will next be described. The decoding device of the present embodiment is configured similarly to the decoding device 100 of the first embodiment or to the decoding device 100a of the second embodiment. The following description describes an example in which the decoding device of the present embodiment is configured similarly to the decoding device 100 of the first embodiment.

The first embodiment has been described with respect to an example in which, in the column operation, data is read from as many register files as the column weight of the corresponding P-column unit of the check matrix, among the multiple register files in the intermediate value storage unit 2. That is, N columns of the check matrix are divided into N/P blocks each having P columns, and data is read from corresponding register files on a per-block basis. In the present embodiment, the number of columns of a column-wise block is not fixed to P, but is defined as P×X, where X is an integer greater than or equal to 1. Thus, the numbers of columns of the respective multiple column blocks generated by column-wise division of the check matrix are each X×P, where the value of X depends on the column blocks.

For example, blocks from a first block to a fourth block are each associated with 2P columns. Assuming, for example, that the column weights of the respective P-column units are {8, 3, 3, 3, 2, 2, 2, 2}, the column weight (block column weight) of the first block is 11, the column weight of the second block is 6, the column weight of the third block is 4, and the column weight of the fourth block is 4. The blocks are defined in this manner, and based on this definition, the register files to be selected for the blocks are defined in a form of a table. This results in, at step S22 of FIG. 4, a process for the first block to select eleven register files, a process for the second block to select six register files, and a process for each of the third block and the fourth block to select four register files. In this case, the value of B_{C} is 4. Thus, one column operation is performed on the four divided blocks.

In addition, the address is incremented by 2 beginning from the initial address to read, from the storage unit 1, data associated with two consecutive addresses for every block generated by division, and the data is input to the P-parallel column computing unit 9. As described above, the method of division into column-wise blocks is different from that of the first embodiment. This may result in a value of the column weight associated with a block, different from the corresponding value in the first embodiment even when a same check matrix is used, but otherwise the column operation in the present embodiment is similar to the column operation in the first embodiment.

The present embodiment can reduce the number of divided blocks to be processed in the column operation as compared to that in the first embodiment, and can thus reduce the number of processing steps required for the decoding process. The present embodiment can accordingly further increase the speed of the decoding process as compared to the first embodiment. Note that an example has been described above in which the decoding device 100 of the first embodiment uses a method of division into blocks different from the method used in the first embodiment. However, the decoding device 100a of the second embodiment may also perform the decoding process using the different method of division into blocks, that is, using a definition of (P×X) columns as one block for performing the foregoing operation. This can further increase the speed of the decoding process as compared to the decoding device 100a of the second embodiment.

In addition, the decoding device described in relation to the third embodiment may further use the method of division into column-wise blocks of the present embodiment. This can further increase the speed of both the row operation and the column operation as compared to the first embodiment or the second embodiment.

The decoding method according to the present disclosure provides an advantage in enabling a reduction in the time required for decoding an LDPC code.

The configurations described in the foregoing embodiments are merely examples. These configurations may be combined with a known other technology, and configurations of different embodiments may be combined together. Moreover, a part of the configurations may be omitted and/or modified without departing from the spirit thereof.

What is claimed is:

1. A decoding method to be performed by a decoding device, the decoding device including a storage circuitry to receive codewords of a low-density parity-check code having a check matrix divisible into P-row by P-column sub-matrices, and store reception data, wherein P is an integer greater than or equal to 2, and an intermediate value storage circuitry having as many storage areas as a number dependent on a column weight of the check matrix, the decoding method comprising:
as a storage of data reproduced, reading the reception data from the storage circuitry in units of P words, reproducing a piece of the data read, based on the column weight of a P-column unit of the check matrix, and writing the pieces of data generated by the reproducing, into respective corresponding ones of the storage areas in the intermediate value storage circuitry;
as a selection of storage areas, reading, on a row block-by-row block basis for row blocks generated by row-wise division of the check matrix, pieces of data from as many the storage areas as a row weight associated with that row block, in the intermediate value storage circuitry;
as a first shifting of data read, shifting as many the pieces of the data as the row weight that have been read in the selection of storage areas, by respective amounts corresponding to respective positions of elements having a value “1” in the check matrix, the elements corresponding to the respective storage areas that are sources of the respective pieces of data;
as a parallel row operation, performing a row operation in parallel on a word-by-word basis using as many pieces of the data as the row weight, obtained by the shifting performed by the first shifting;
as a second shifting of operational results, shifting as many operational results as the row weight, obtained by the parallel row operation, to undo the shifting performed in the first shifting;
as a first update, updating values in corresponding ones of the storage areas in the intermediate value storage circuitry with the as many operational results as the row weight that have undergone the shifting performed by the second shifting;
as a first control, causing the selection of storage areas, the first shifting, the parallel row operation, the second shifting, and the first update to be performed for all the row blocks; and
as a column operation, performing a column operation using values stored in the respective storage areas in the intermediate value storage circuitry after performing the first control.

2. The decoding method according to claim 1, wherein the plurality of sub-matrices constituting the check matrix are each one of a unit matrix, a quasi-unit matrix, a shift matrix, a sum matrix, and a null matrix, the quasi-unit matrix being a matrix having at least one element, among elements having a value “1” of the unit matrix, being replaced with “0”, the shift matrix being a matrix obtained by cyclically shifting the unit matrix or the quasi-unit matrix, the sum matrix being a sum of at least two matrices that are each one of the unit matrix, the quasi-unit matrix, and the shift matrix.

3. The decoding method according to claim 1, wherein the column operation includes:
as a read of data, reading, on a column block-by-column block basis for column blocks generated by column-wise division of the check matrix, data from as many the storage areas as a block column weight associated with that column block, in the intermediate value storage circuitry;
as a parallel column operation, performing a column operation in parallel on a word-by-word basis using as many pieces of the data as the block column weight, read in the read of data, and using the reception data;
as a second update, updating values in corresponding ones of the storage areas in the intermediate value storage circuitry, with as many operational results as the block column weight, obtained by the parallel column operation; and
as a second control, causing the read of data, the parallel column operation, and the second update to be performed for all the column blocks.

4. The decoding method according to claim 3, wherein numbers of columns of the respective plurality of column blocks generated by the column-wise division of the check matrix are each X×P, where X is an integer greater than or equal to 1, and X has a value determined depending on the column blocks.

5. The decoding method according to claim 1, wherein numbers of rows of the respective plurality of row blocks generated by the row-wise division of the check matrix are each X×P, where X is an integer greater than or equal to 1, and X has a value determined depending on the row blocks.

6. The decoding method according to claim 1, wherein
the storage circuitry includes a first storage circuitry and a second storage circuitry, and
the decoding method comprises:
as a first writing, writing one codeword of the reception data into the first storage circuitry;
as a switching, upon completion of writing of the one codeword of the reception data into the first storage circuitry, switching a destination of writing the reception data to the second storage circuitry; and
performing a decoding process using a portion of the reception data stored in the first storage circuitry, the decoding process performed while the reception data is being written into the second storage circuitry.

7. A decoding device comprising:
a storage circuitry to receive codewords of a low-density parity-check code having a check matrix divisible into P-row by P-column sub-matrices, and to store reception data, wherein P is an integer greater than or equal to 2;
an intermediate value storage circuitry having as many storage areas as a number dependent on a column weight of the check matrix;
a selection circuitry to read, on a row block-by-row block basis for row blocks generated by row-wise division of the check matrix, pieces of data from as many the storage areas as a row weight associated with that row block, in the intermediate value storage circuitry;
a first shifting circuitry to perform a shift operation on as many the pieces of the data as the row weight, read by the selection circuitry, by respective amounts corresponding to respective positions of elements having a value “1” in the check matrix, the elements corresponding to the respective storage areas that are sources of the respective pieces of data;
a parallel row computing circuitry to perform a row operation in parallel on a word-by-word basis using as many pieces of the data as the row weight, obtained by the shift operation performed by the first shifting circuitry;
a second shifting circuitry to perform a shift operation on as many operational results as the row weight, obtained by the parallel row computing circuitry, to undo the shift operation performed by the first shifting circuitry;
a control circuitry to provide control to cause the reception data to be read from the storage circuitry in units of P words, to cause a piece of the data read to be reproduced based on the column weight of a P-column unit of the check matrix, and to cause the pieces of data generated by reproduction, to be written into respective corresponding ones of the storage areas in the intermediate value storage circuitry, and to provide control to cause values in corresponding ones of the storage areas in the intermediate value storage circuitry to be updated with the as many operational results as the row weight that have undergone the shift operation performed by the second shifting circuitry; and
a column operation processing circuitry to perform a column operation using values stored in the respective storage areas in the intermediate value storage circuitry after performing the row operation.

8. A control circuit for controlling a communication device, the communication device including a storage circuitry to receive codewords of a low-density parity-check code having a check matrix divisible into P-row by P-column sub-matrices, and store reception data, wherein P is an integer greater than or equal to 2, and an intermediate value storage circuitry having as many storage areas as a number dependent on a column weight of the check matrix, the control circuit causing the communication device to perform:
as a storage of data reproduced, reading the reception data from the storage circuitry in units of P words, reproducing a piece of the data read, based on the column weight of a P-column unit of the check matrix, and writing the pieces of data generated by the reproducing, into respective corresponding ones of the storage areas in the intermediate value storage circuitry;
as a selection of storage areas, reading, on a row block-by-row block basis for row blocks generated by row-wise division of the check matrix, pieces of data from as many the storage areas as a row weight associated with that row block, in the intermediate value storage circuitry;
as a first shifting of data read, shifting as many the pieces of the data as the row weight that have been read in the selection of storage areas, by respective amounts corresponding to respective positions of elements having a value “1” in the check matrix, the elements corresponding to the respective storage areas that are sources of the respective pieces of data;
as a parallel row operation, performing a row operation in parallel on a word-by-word basis using as many pieces of the data as the row weight, obtained by the shifting performed by the first shifting;
as a second shifting of operational results, shifting as many operational results as the row weight, obtained by the parallel row operation, to undo the shifting performed in the first shifting;
as a first update, updating values in corresponding ones of the storage areas in the intermediate value storage circuitry with the as many operational results as the row weight that have undergone the shifting performed by the second shifting;
as a first control, causing the selection of storage areas, the first shifting, the parallel row operation, the second shifting, and the first update to be performed for all the row blocks; and
as a column operation, performing a column operation using values stored in the respective storage areas in the intermediate value storage circuitry after performing the first control.

9. A non-transitory computer-readable program storage medium storing a program for controlling a communication device, the communication device including a storage circuitry to receive codewords of a low-density parity-check code having a check matrix divisible into P-row by P-column sub-matrices, and store reception data, wherein P is an integer greater than or equal to 2, and an intermediate value storage circuitry having as many storage areas as a number dependent on a column weight of the check matrix, wherein
the program causes the communication device to perform:
as a storage of data reproduced, reading the reception data from the storage circuitry in units of P words, reproducing a piece of the data read, based on the column weight of a P-column unit of the check matrix, and writing the pieces of data generated by the reproducing, into respective corresponding ones of the storage areas in the intermediate value storage circuitry;
as a selection of storage areas, reading, on a row block-by-row block basis for row blocks generated by row-wise division of the check matrix, pieces of data from as many the storage areas as a row weight associated with that row block, in the intermediate value storage circuitry;
as a first shifting of data read, shifting as many the pieces of the data as the row weight that have been read in the selection of storage areas, by respective amounts corresponding to respective positions of elements having a value “1” in the check matrix, the elements corresponding to the respective storage areas that are sources of the respective pieces of data;
as a parallel row operation, performing a row operation in parallel on a word-by-word basis using as many pieces of the data as the row weight, obtained by the shifting performed by the first shifting;
as a second shifting of operational results, shifting as many operational results as the row weight, obtained by the parallel row operation, to undo the shifting performed in the first shifting;
as a first update, updating values in corresponding ones of the storage areas in the intermediate value storage circuitry with the as many operational results as the row weight that have undergone the shifting performed by the second shifting;
as a first control, causing the selection of storage areas, the first shifting, the parallel row operation, the second shifting, and the first update to be performed for all the row blocks; and
as a column operation, performing a column operation using values stored in the respective storage areas in the intermediate value storage circuitry after performing the first control.
